(19) United States
(12) Patent Application Publication
(10) Pub. No.: US 2026/0018444 A1
(43) Pub. Date: Jan. 15, 2026

(54) METHODS FOR REDUCING DEFECTS DURING DIE PLACEMENT

(71) Applicant: Taiwan Semiconductor Manufacturing Company, LTD., Hsinchu (TW)

(72) Inventors: Yi-Fong Lai, Changhua (TW); Chung-Chuan Tseng, Hsinchu (TW); Po-Yu Chen, Hsinchu (TW); Li-Wen Ho, Hsinchu (TW); Yu-Chen Deng, Taoyuan (TW)

(21) Appl. No.: 18/766,885

(22) Filed: Jul. 9, 2024

(51) Int. Cl. H01L 21/673; H01L 21/683

(52) U.S. Cl. CPC H01L 21/67336; H01L 21/6836

(57) ABSTRACT

A die transfer system includes a carrier wafer with an adhesive layer on an upper surface of the carrier wafer that comprises a patterned bottom layer and a guard ring over a perimeter of the carrier wafer.

### BACKGROUND

Semiconductor packages containing integrated circuits are becoming increasingly complex. For example, System on Integrated Chip (SoIC) has been developed to include a plurality of device dies such as processors and memory cubes which are stacked vertically and interconnected. The device dies can be formed using different technologies and have different functions, and can be heterogeneously combined to obtain desired functionality, thus forming a system which is combined in one chip carrier package. This reduces manufacturing costs and optimizes device performance. Similar three-dimensional packages include System in Package (SiP), Wafer Level Package (WLP), and Package on Package (PoP).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an upper plan view of a wafer carrier with a wafer substrate containing a plurality of dies, in accordance with some embodiments of the present disclosure.

FIG. 1B is a cross-sectional view of the wafer carrier with a wafer containing a plurality of dies along line B-B of FIG. 1A.

FIG. 2 is a flow chart illustrating a first method for constructing a wafer carrier, in accordance with some embodiments.

FIG. 3 is a side cross-sectional view after a first carrier wafer has been bonded to the front side of a device wafer (i.e., a wafer substrate containing a plurality of dies) to form a composite structure.

FIG. 4 is a side cross-sectional view after the thickness of the device wafer has been reduced.

FIG. 5A is a side cross-sectional view after a perimeter of the device wafer is trimmed.

FIG. 5B is a lower plan view of the composite structure along line B-B of FIG. 5A.

FIG. 6 is a side cross-sectional view of the composite structure after planarization of the device wafer. The dies are exposed from the backside.

FIG. 7 is a side cross-sectional view of the composite structure after formation of a dielectric layer on the backside of the device wafer.

FIG. 8 is a side cross-sectional view of the composite structure after the dielectric layer has been patterned.

FIG. 9 is a side cross-sectional view of the composite structure after an adhesive material has been deposited to form a patterned bottom layer and a guard ring around the perimeter of the device wafer.

FIG. 10 is a side cross-sectional view of the composite structure after a second carrier wafer is bonded to the adhesive material.

FIG. 11 is a side cross-sectional view of the composite structure after the first carrier wafer is removed.

FIG. 12 is a side cross-sectional view of the composite structure after the patterned dielectric layer is removed. The dies are now separated from each other as well.

FIG. 13A is a side cross-sectional view of the wafer carrier after an etch stop layer is removed from the front side of the dies.

FIG. 13B is a lower plan view of the wafer carrier along line B-B of FIG. 13A.

FIG. 14 is a flow chart illustrating a first method for using the wafer carrier to reduce defects, especially in display panel fabrication, in accordance with some embodiments.

FIG. 15 is a side cross-sectional view showing an individual die being removed from the wafer carrier by a pick-and-place machine.

FIG. 16 is a side cross-sectional view showing the individual die being placed upon a substrate, such as a display panel.

FIG. 17 is a side cross-sectional view of the wafer carrier after all dies have been removed.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The terms “die”, “chip”, or “integrated circuit” are used interchangeably in the present disclosure to refer to a semiconductor device formed from interconnected electronic components. The semiconductor device also includes one or more interconnect layers that permit components on the device to communicate with each other, or permit the device to communicate with one or more other devices. Examples of an interconnect layer may include a redistribution layer (RDL) or an interposer having bond pads or C4 bumps or pillars. The semiconductor device may have an interconnect layer on only one side, or on both sides.

The present disclosure relates to systems and methods for reducing defects during die placement. This may relate to the integration of individual dies into a larger semiconductor package, or for example the integration of one or more individual dies onto a larger substrate, such as a Display Driver Integrated Circuit (DDIC) for an LED display panel. Pick-and-place machines or systems are automatic systems that can pick up an individual die and place it onto another die or a host wafer, often at very high speeds. In common manufacturing processes, a large number of dies is concurrently made on a wafer substrate. The wafer substrate is then adhered to a wafer carrier using benzocyclobutene (BCB) as an adhesive, and the dies are then separated from each other in a process known as dicing. To remove residual particles that may be present due to the dicing process, cleaning is performed, for example by using an air knife. The bonding force of BCB is relatively weak (to enhance pick-and-place), and the forces exerted by the cleaning process can cause dies on the edge to fly off of the wafer carrier. The die can then land unpredictably and cause defects, whether to the die itself or to the substrate upon which the die is to be placed. In the systems of the present disclosure, a guard ring is included around the wafer substrate/dies to provide a sidewall that provides consolidation forces and reduces such defects.

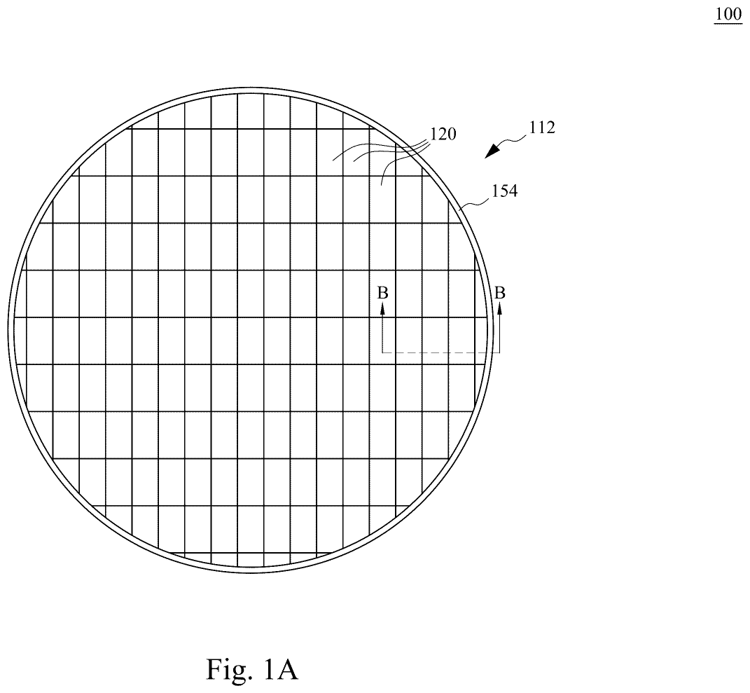

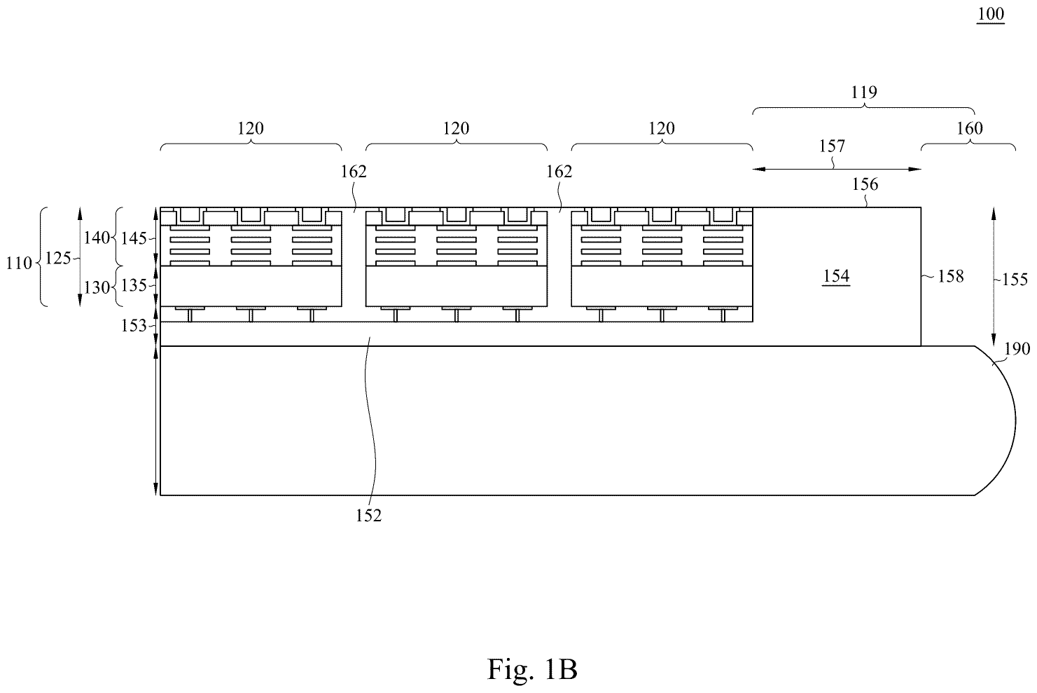

FIG. 1A is an upper plan view of a die transfer system 100 of the present disclosure, which may also be called a wafer carrier. A device wafer containing a plurality of dies is also illustrated. FIG. 1B is a cross-sectional view of the wafer carrier with the device wafer along line B-B of FIG. 1A.

Referring first to FIG. 1A, a first or front side 112 of the device wafer 110 is illustrated. A plurality of individual dies 120 has been formed on the device wafer. The number of dies per wafer is a function of the wafer size and the die size. A guard ring 154 is visible over or around the perimeter of the device wafer 110.

Referring now to FIG. 1B, the perimeter of the die transfer system is illustrated. Three individual dies 120 of the device wafer are visible. As shown here, the three dies are joined together by a gap fill material 162, which is commonly a dielectric oxide. Each die 120 includes a substrate 130 and one or more interconnect layers 140. The bottom surfaces of the dies 120 are bonded to a patterned bottom layer 152 formed from an adhesive material, which is in turn bonded to a carrier wafer 190. A guard ring 154 or sidewall is present around the perimeter 119 of the device wafer. The guard ring is formed from the same adhesive material as the patterned bottom layer 152. The guard ring may also be described as being formed on a perimeter of the carrier wafer 190. Optionally, the carrier wafer may also include an uncoated “trim” area 160 on the perimeter around the outer side 158 of the guard ring. This area may correspond to the edge bead removal (EBR) area of the substrate. The guard ring itself has an annular or ring shape.

As indicated in FIG. 1B, the substrate has a height 135 and the interconnect layer(s) have a height 145. The bottom layer 152 also has a height 153. The guard ring 154 has a height 155 and a width 157. A top surface 156 of the guard ring is also labelled.

In particular embodiments, the height 135 of the substrate may range from about 1 micrometer (μm) to about 5 μm, depending on its construction. In some embodiments, the height 145 of the interconnect layer(s) may be from about 5 μm to about 80 μm, depending on the number of layers and their individual height. In various embodiments, the height 153 of the bottom layer may be from about 10 μm to about 30 μm. In particular embodiments, the height 155 of the guard ring may be from about 30 μm to about 110 μm. The height 155 of the guard ring is greater than the height 153 of the bottom layer. Generally, the height 155 of the guard ring should be equal or greater than the height 125 of the dies. Put another way, the top surface 156 of the guard ring is above or higher than the dies. In particular embodiments, the width 157 of the guard ring may be from about 1 μm to about 5 μm. Other ranges and values are contemplated for each of these measurements, and are within the scope of this disclosure.

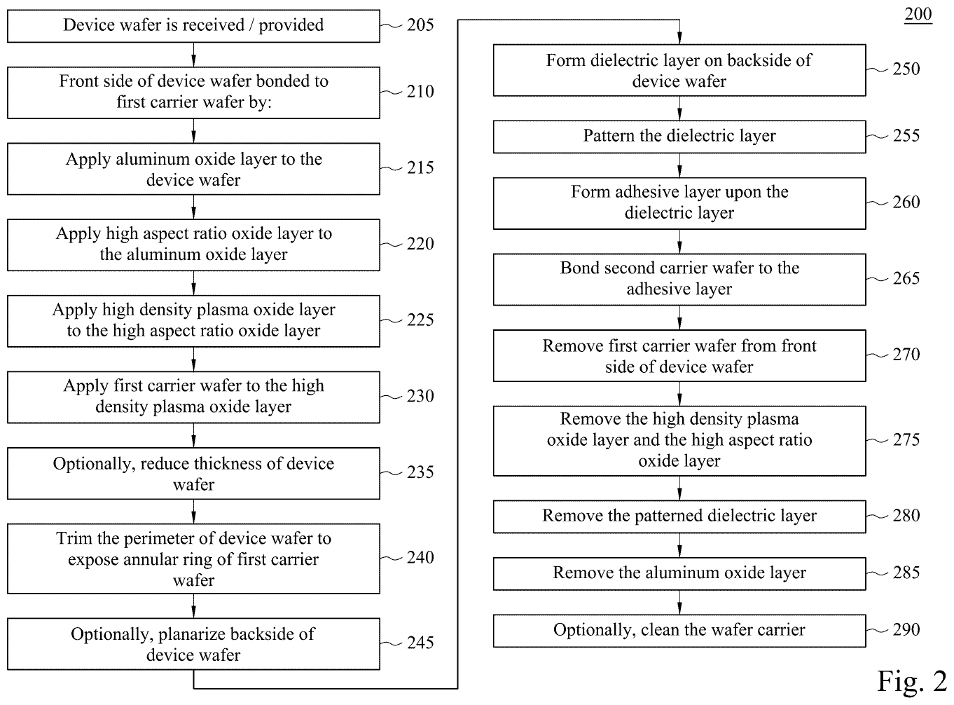

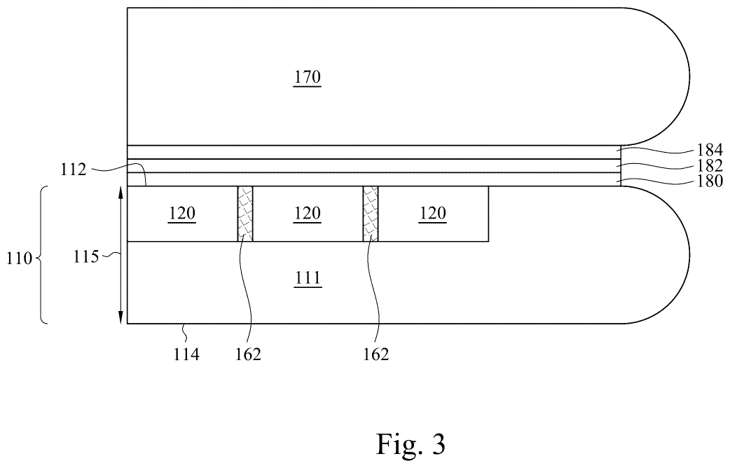

FIG. 2 is a flow chart illustrating a first method for constructing a wafer carrier, in accordance with some embodiments. FIGS. 3-13B illustrate various steps of the method of FIG. 2, and these figures are discussed together. It is noted that in the various steps, the orientation of the various components is maintained, even though the process operations described may not be performed with the components in that specific orientation. For example, flipping of the structures may be performed during deposition of various layers, but such flipping is not illustrated.

Referring first to FIG. 3, a device wafer 110 is illustrated. The device wafer is illustrated as a substrate 111 that contains a plurality of dies 120 formed thereon, with gap fill material 162 between the dies. It is noted that as illustrated, the dies 120 are present on the first or front side 112 of the device wafer, and they do not extend all the way through to the second or backside 114 of the device wafer. The first/front side is the side opposite that of the second/backside of the device wafer. However, this is not required, and it is contemplated in some embodiments that the dies 120 could extend completely through the substrate 111. The dies may be, for example, a Display Driver Integrated Circuit (DDIC).

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits/dies 120 are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), tantalum oxide (Ta₂O₅), zirconium dioxide (ZrO₂), or hafnium dioxide (HfO₂); nitrides such as silicon nitride (SiN) or silicon oxynitride (SiON); silicates like hafnium silicate (HfSiO₄) or zirconium silicate (ZrSiO₄); polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material. As previously mentioned, interconnect layer(s) are also present on each die.

Gap fill material 162 is illustrated here on the sides of the dies. In certain embodiments, the gap fill material is dielectric, and can be an organic dielectric material such as epoxy resin, or an inorganic dielectric material such as an oxide. In particular embodiments, the gap fill material is silicon dioxide.

Initially, then, in step 205 of FIG. 2, and as illustrated in FIG. 3, a device wafer 110 is provided or received. Next, in step 210, the first or front side 112 of the device wafer 110 is bonded to a first carrier wafer 170. In some particular embodiments, this is done by first applying an aluminum oxide layer 180 to the device wafer 110, as indicated in step 215. Next, in step 220, a high aspect ratio oxide layer 182 is applied to the aluminum oxide layer 180. Then, in step 225, a high density plasma oxide layer 184 is applied to the high aspect ratio oxide layer 182. Then, in step 230, the first carrier wafer 170 is applied to the high density plasma oxide layer 184. It is noted that the thicknesses of three bonding layers 180, 182, 184 are exaggerated in this illustration for visibility and in practice are very thin.

The aluminum oxide layer 180 may be formed by physical vapor deposition (PVD), chemical vapor deposition (CVD), atomic layer deposition (ALD), or other suitable technique. The aluminum oxide layer may be, for example, formed from Al₂O₃. The high aspect ratio oxide layer 182 may be, for example, a high-density-plasma silicon dioxide (HDP-SiO₂) or a silicon-rich oxide layer deposited by plasma-enhanced CVD process (PECVD silicon dioxide). By way of example, high-density-plasma silicon dioxide (HDP-SiO₂) may be deposited using a conventional chemical vapor deposition (CVD) process combined with a simultaneous sputtering process. The CVD process may use a gas mixture including, for example, silane, oxygen and argon. The high density plasma oxide layer 184 may also be formed by similar processes. These two layers 182, 184 may be resistant to conventional etching processes. The first carrier wafer 170 is usually also made of silicon, or the same material as the device wafer 110.

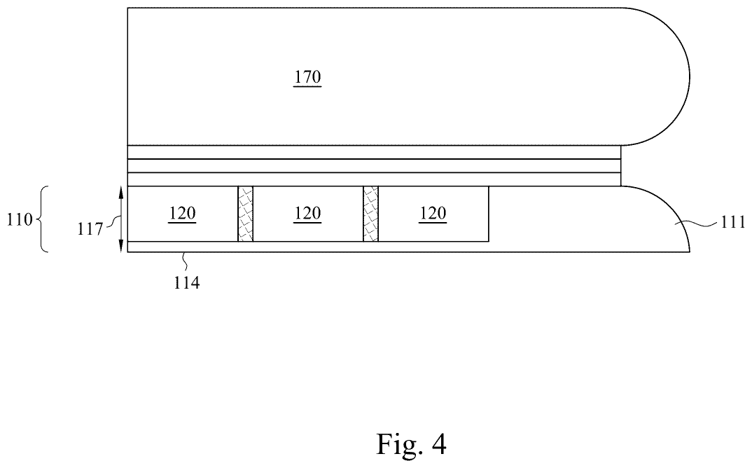

Optionally, in step 235 of FIG. 2, and as illustrated in FIG. 4, the thickness of the device wafer may be reduced, or in other words the device wafer is thinned. This may be performed, for example, by grinding the second side or backside 114 of the device wafer 110. Referring back to FIG. 3, the device wafer 110 usually has a thickness 115 sufficient to provide mechanical stability and avoid warping, for example about 750 μm. However, the die 120 may have a much smaller thickness, and the reduction in thickness aids in continued processing. In FIG. 4, the device wafer thickness 117 is less than the thickness 115 in FIG. 3. As illustrated here, a portion of the device wafer substrate 111 is still present and the dies 120 are not yet exposed.

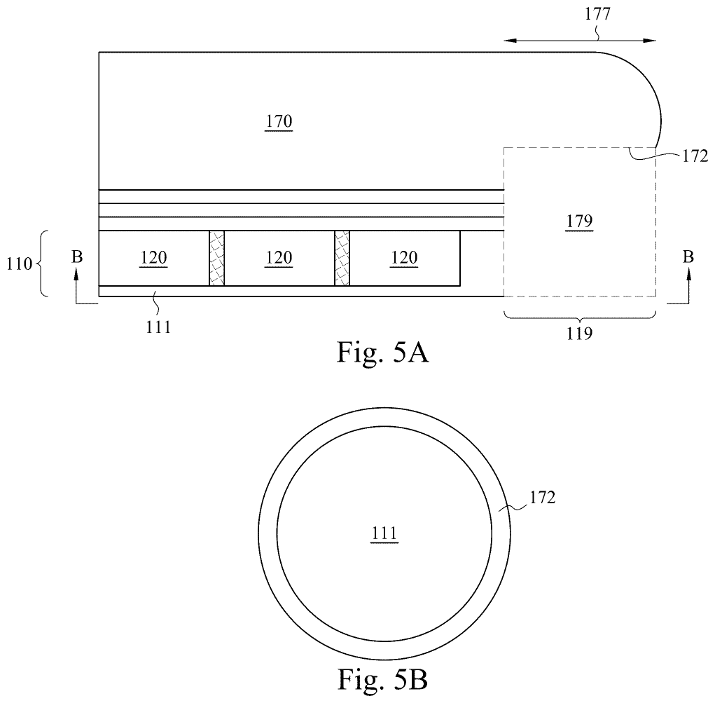

Next, in step 240 of FIG. 2, and as illustrated in FIG. 5A and FIG. 5B, the perimeter 119 of the device wafer 110 is trimmed to expose an annular portion or ring 172 formed from a first side or backside of the first carrier wafer 170. This may be done, for example, by mechanical trimming of the perimeter. In FIG. 5A, the dotted volume 179 indicates where material has been removed relative to FIG. 4 to form the annular portion, which is illustrated here as having a rectangular or square cross-section. As illustrated here, some of the substrate 111 is shown as still being present on the side of the dies 120, or at the same level thereof. This is not required, but may occur, and alternatively additional gap fill material could be present in this location as well. In FIG. 5B, the exposed annular portion or ring 172 is visible, surrounding the substrate 111 of the device wafer. In particular embodiments, the annular portion or ring may have a width 177 of about 2 micrometers to about 5 micrometers, although other ranges and values are also within the scope of the present disclosure.

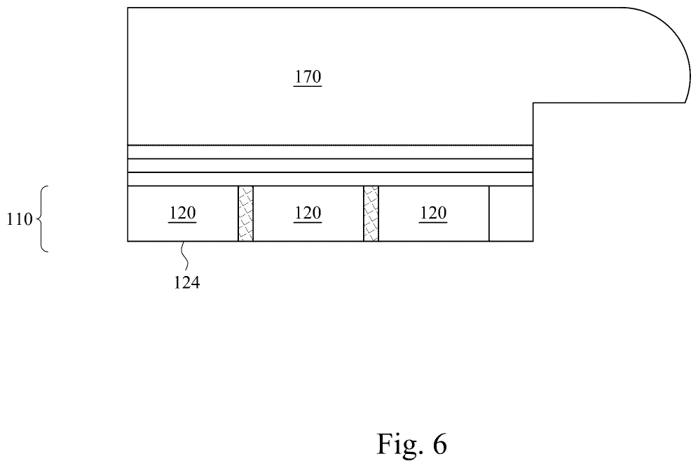

In optional step 245 of FIG. 2, and as illustrated in FIG. 6, the second or backside 114 of the device wafer 110 is further planarized. This may be done by chemical mechanical polishing (CMP), where the surface of a wafer is leveled using relative motion between the wafer and a rotating polishing pad to which a slurry is applied. Downward pressure is applied to push the wafer against the polishing pad, and elevated elements are worn down to obtain a surface with low surface roughness. As illustrated in FIG. 6, the bottom surfaces 124 of the dies are now exposed.

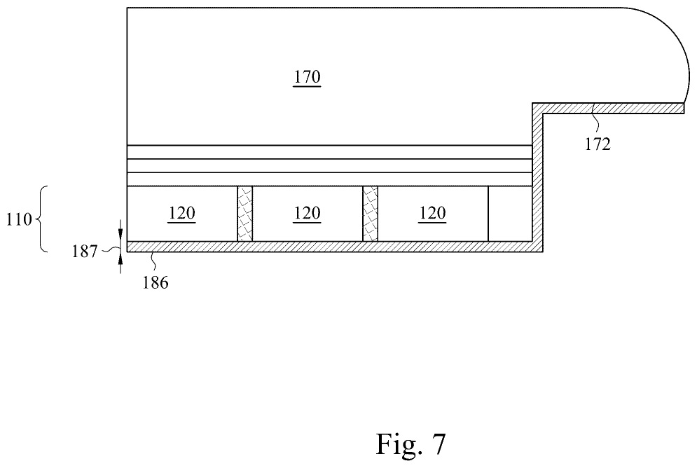

Next, in step 250 of FIG. 2, and as illustrated in FIG. 7, a dielectric layer 186 is formed upon the backside of the device wafer 110. The dielectric layer is formed from a dielectric material, and is typically formed from materials such as silicon dioxide (SiO₂), silicon nitride (Si₃N₄), aluminum oxide (AlOₓ), aluminum nitride (AlN), hafnium oxide (HfOₓ), silicon carbonitride (SiCₓN_{y}), or silicon oxycarbide (SiCₓO_{y}). In particular embodiments, the dielectric layer is formed from silicon dioxide. The first dielectric layer can be formed by physical vapor deposition (PVD) or chemical vapor deposition (CVD) or other suitable process. For example, a silicon-containing source gas may act as a silicon precursor that reacts with an oxygen-containing source gas. Examples of such silicon precursors include but are not limited to tetraethyl orthosilicate (TEOS), trimethylsilane, tetramethylsilane, and hexachlorodisilane (HCDS). Ozone (O₃) can be used to provide oxygen atoms for the reaction. At temperatures of about 300° C. to about 500° C. or higher, these gases will react to deposit silicon dioxide. The dielectric layer may then be planarized to obtain a flat surface, if desired. As illustrated in FIG. 7, the dielectric layer 186 covers the bottom surfaces of the dies 120. The dielectric layer may also be formed upon other exposed surfaces, such as the perimeter of the device wafer and the annular portion 172 of the first carrier wafer 170. In particular embodiments, the dielectric layer may have a thickness 187 of about 3000 angstroms to about 10,000 angstroms, although other ranges and values are within the scope of the present disclosure.

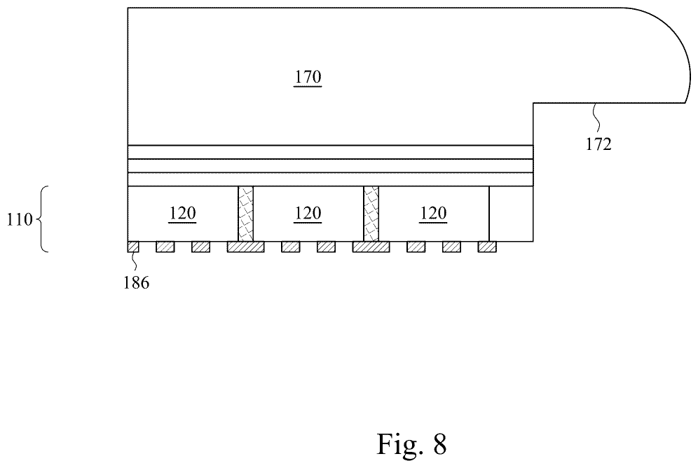

Then, in step 255 of FIG. 2, and as illustrated in FIG. 8, the dielectric layer 186 is patterned. Generally, the pattern exposes only small portions of the bottom surfaces of the dies 120, for the later application of adhesive. In addition, the patterning removes the dielectric layer from other locations such as the perimeter of the device wafer and the annular portion 172 of the first carrier wafer 170.

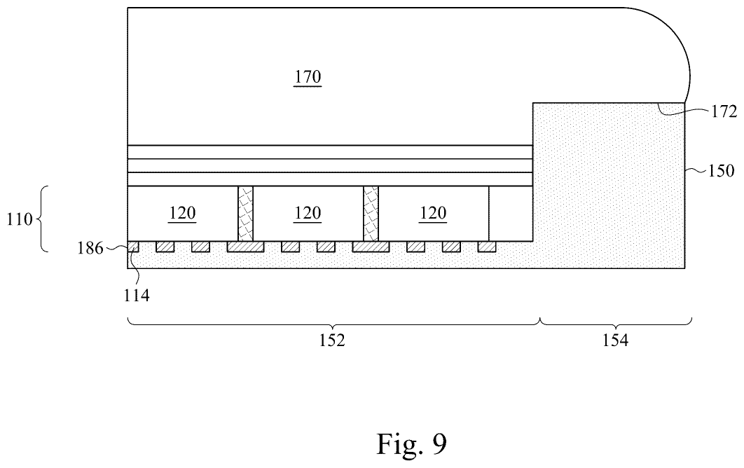

Continuing, in step 260 of FIG. 2, and as illustrated in FIG. 9, an adhesive material is deposited over the backside 114 of the device wafer 110 and the annular portion 172 of the first carrier wafer 170 to form an adhesive layer 150. In particular embodiments, the adhesive material is benzocyclobutene (BCB), although any suitable adhesive material may be used. It is noted that BCB exists in a dry etch version and a photosensitive version, and either version may be used. The adhesive layer fills the patterned dielectric layer 186, and the resulting patterned bottom layer 152 is one part of the adhesive layer. The adhesive material also forms a guard ring 154 around the perimeter of the device wafer, and the guard ring 154 is another part of the adhesive layer. As can be seen here, the adhesive material also covers the annular portion 172 on the first side or backside of the first carrier wafer 170. The guard ring itself will have an annular shape.

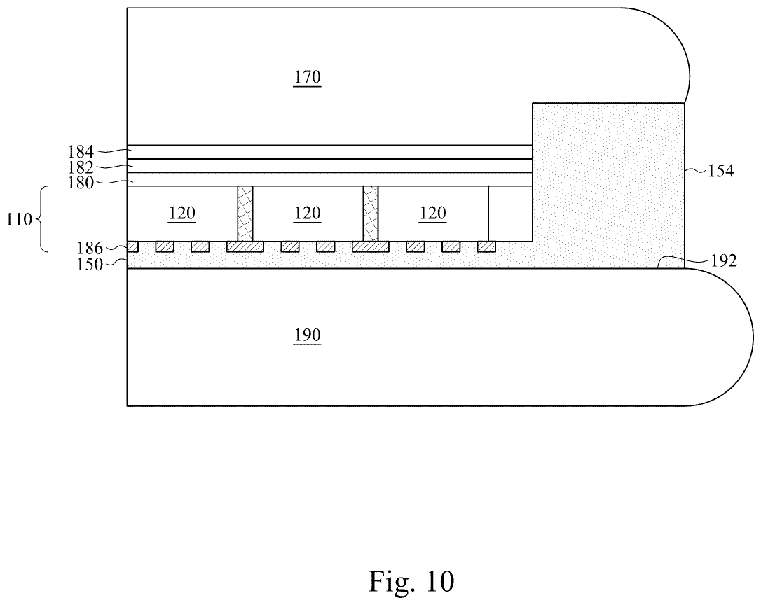

In step 265 of FIG. 2, and as illustrated in FIG. 10, a second carrier wafer 190 is then bonded to the adhesive layer 150. The second carrier wafer 190 is usually also made of silicon, or the same material as the device wafer 110. The adhesive layer 150 may be described as being located on an upper surface 192 of the second carrier wafer. The guard ring 154 can be described as being located around a perimeter of the carrier wafer.

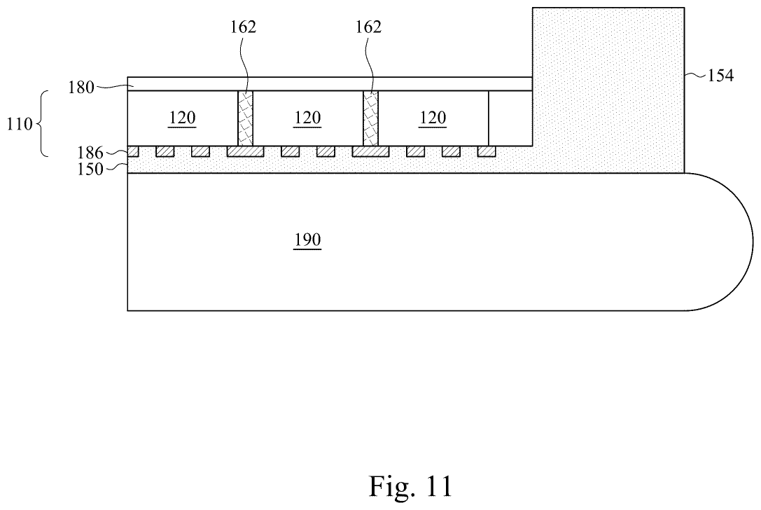

Next, still referring to FIG. 10, in step 270 of FIG. 2, the first carrier wafer 170 is removed from the front side of the device wafer 110. This may be done using conventional debonding techniques such as thermal debonding, mechanical debonding, or chemical debonding as appropriate. In addition, in step 275 of FIG. 2, the high density plasma oxide layer 184 and the high aspect ratio oxide layer 182 are removed from the front side of the device wafer 110 as well. This may be done, for example, by etching or other suitable process. It is noted that steps 270 and 275 may be performed concurrently if desired. The resulting structure is illustrated in FIG. 11.

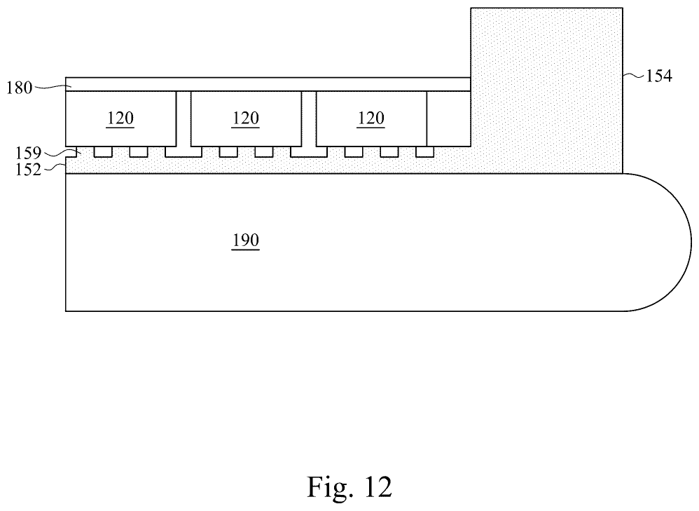

Next, in step 280 of FIG. 2, the patterned dielectric layer 186 is removed. This may be performed, for example, using a vapor hydrogen fluoride (VHF) etch or other suitable technique. It is noted that the gap fill material 162 between the dies 120 is commonly made of the same material as the patterned dielectric layer 186, and thus is also etched in this processing step as well to separate the dies 120 from each other. The aluminum oxide layer 180 can act as an etch stop layer to prevent undesired etching of dielectric layers on the dies themselves. It is noted that steps 275 and 280 may be performed concurrently if desired (i.e. the high density plasma oxide layer 184 and the high aspect ratio oxide layer 182 are also etched by VHF). The resulting structure is illustrated in FIG. 12. There is now a space between the patterned bottom layer 152 and the dies 120, with adhesive pillars 159 connecting to the dies.

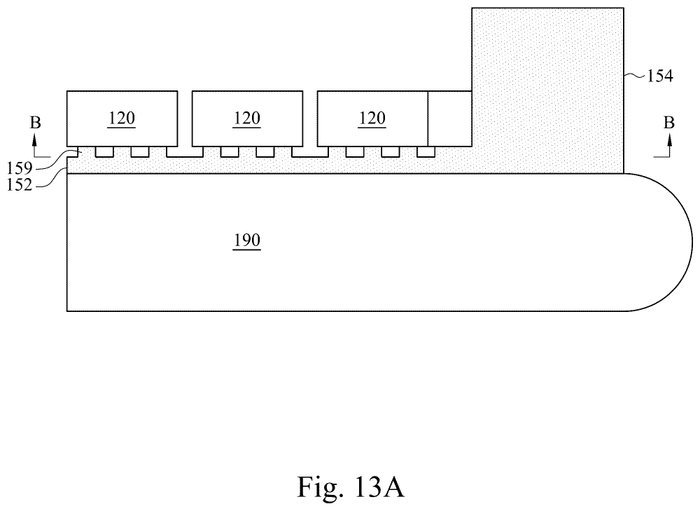

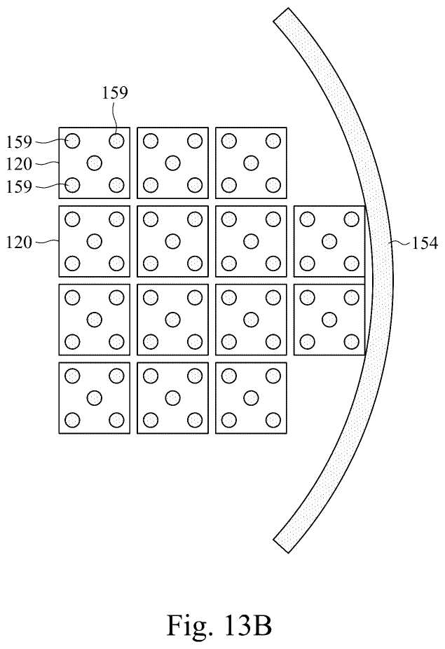

In step 285 of FIG. 2, the aluminum oxide layer 180 is removed. This may be done, for example, by etching or other suitable process. The resulting die transfer system 100 is illustrated in FIG. 13A and FIG. 13B. As seen in these two figures, the dies 120 are held on their bottom surface by adhesive pillars 159 that were formed by the patterned dielectric layer. Five adhesive pillars 159 are illustrated here per die, but any suitable number of pillars may be used. The adhesive pillars may have the same or different shapes. In addition, the guard ring 154 provides a sidewall that prevents the dies from undesired removal due to air knife cleaning or similar processes that exert pressure on the dies. An optional cleaning 290 of the die transfer system/wafer carrier may be performed here, if desired, to remove any contaminants or byproducts.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

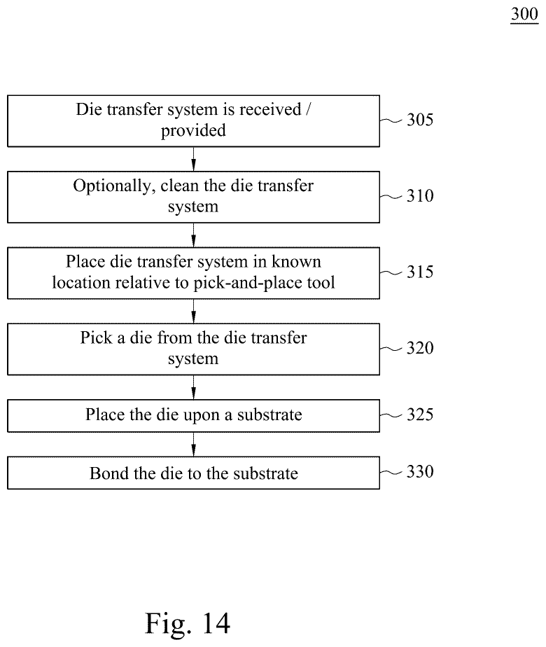

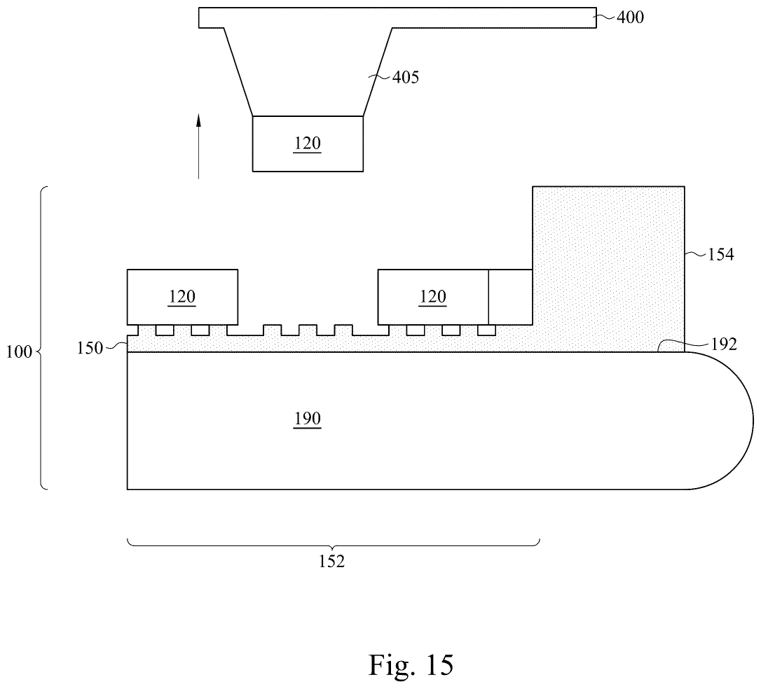

FIG. 14 is a flow chart illustrating a method for placing a die upon a substrate, in accordance with some embodiments. FIGS. 15-17 illustrate various steps of the method of FIG. 14.

Initially, in step 305 of FIG. 14 and referring to FIG. 13A and FIG. 13B and FIG. 15, a die transfer system 100 is provided or received. The die transfer system 100 includes a carrier wafer 190, the adhesive layer 150 on the upper surface 195 of the carrier wafer, and a plurality of dies 120. The adhesive layer 150 includes a bottom layer 152 to which the dies 120 are adhered, and also includes a guard ring 154 over or around the perimeter of the carrier wafer. The dies 120 are surrounded by the guard ring 154.

It is noted that the die transfer system 100 may be formed in one tool or location, with the method steps of FIG. 14 occurring in a different tool or location. Thus, in optional step 310 of FIG. 14, the die transfer system 100 may be cleaned to remove contaminants that may be present, for example using an air knife. Whereas previously the air pressure might dislodge dies on the edge and cause them to fly off the die transfer system and cause defects, the presence of the guard ring now provides a structure that keeps such dies in place. This reduces defects that may occur during the fabrication process of a semiconductor package or larger devices.

In step 315 of FIG. 14, the die transfer system is then placed in a known location relative to a pick-and-place machine/tool. Next, in step 320 of FIG. 14, a die 120 is picked from the die transfer system 100. As illustrated in FIG. 15, this can be done using a pick-and-place machine. The machine uses an arm 400 with one or more pickup nozzles 405 to pick up the die 120 using vacuum pressure (i.e. suction) or electrostatic forces. Not illustrated here may be additional components such as a conveyor belt that transports the arm/die to the desired location, an inspection system to inspect the die and see if it is damaged or missing and compensate for any registration errors, etc.

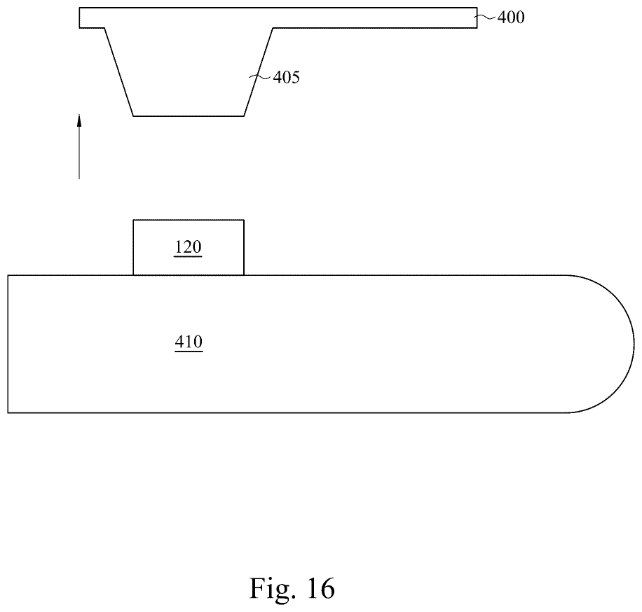

Next, in step 325 of FIG. 14 and as illustrated in FIG. 16, the die 120 is placed upon a substrate 410. The substrate could be, for example, a glass substrate for a display panel (e.g. Chip-On-Glass), or a flexible substrate for a flexible display (e.g. Chip-On-Film), or a plastic substrate (e.g. Chip-On-Plastic). The substrate could also be, for example, another die or chip, for forming a semiconductor package. In step 330 of FIG. 14, the die is then bonded to the substrate using appropriate techniques. Fusion bonding or hybrid bonding could be used to form an interconnection between two dies.

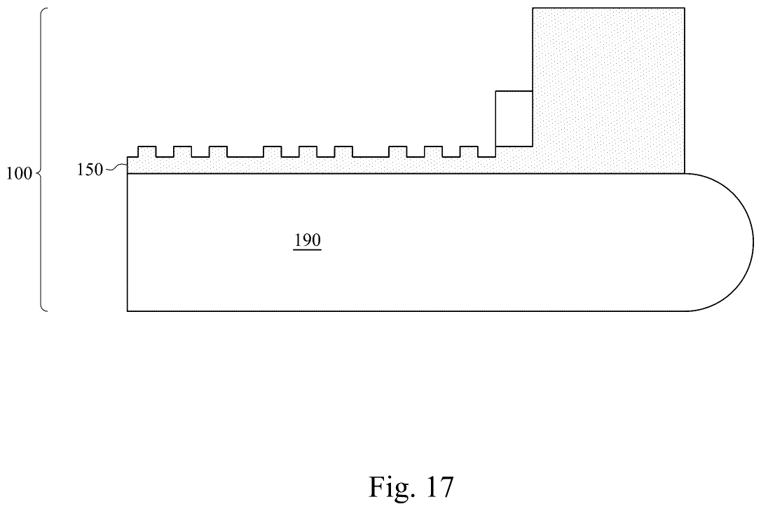

FIG. 17 shows the wafer carrier 100 after all dies have been picked. The wafer carrier may be disposed of, or the adhesive layer 150 could be removed and the carrier wafer 190 could be reused. The adhesive could be removed, for example, using chemical or mechanical means.

The structures of the present disclosure provide some advantages. Defects due to dies unexpectedly separating from the carrier wafer are reduced. This improves yield as well. No extra processing steps or masks are needed either.

Some embodiments of the present disclosure thus relate to methods for constructing a wafer carrier. The first or front side of a device wafer is bonded to a first carrier wafer. A perimeter of the device wafer is trimmed to expose an annular portion of a first side or backside of the first carrier wafer. A dielectric layer is formed upon a second side or backside of the device wafer, and then patterned. An adhesive material is deposited upon the patterned dielectric layer to form an adhesive layer. The adhesive layer also forms a guard ring around the perimeter of the device wafer. A second carrier wafer is then bonded to the adhesive layer. The first carrier wafer is removed. The patterned dielectric layer is also removed.

Other embodiments disclosed herein relate to die transfer systems or wafer carriers. Such systems include a carrier wafer; a patterned adhesive layer on an upper surface of the carrier wafer; and a guard ring on the upper surface of the carrier wafer located over a perimeter of the carrier wafer.

Also described in various embodiments herein are methods for placing a die on a substrate, or methods for reducing defects on a substrate during fabrication. A die transfer system as described herein is provided or received, with a plurality of dies being present thereon. A die is picked from the die transfer system, and placed upon a substrate. The substrate may be, for example, part of a display panel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for constructing a wafer carrier, comprising:
bonding a first side of a device wafer to a first carrier wafer;
trimming a perimeter of the device wafer to expose an annular portion of a first side of the first carrier wafer;
forming a patterned dielectric layer upon a second side of the device wafer, wherein the second side of the device wafer is opposite the first side of the device wafer;
depositing an adhesive material upon the patterned dielectric layer to form an adhesive layer, wherein the adhesive layer forms a guard ring around the perimeter of the device wafer;
bonding a second carrier wafer to the adhesive layer; and
removing the first carrier wafer.

2. The method of claim 1, further comprising removing the patterned dielectric layer.

3. The method of claim 1, further comprising reducing a thickness of the device wafer prior to trimming the perimeter of the device wafer.

4. The method of claim 1, further comprising planarizing the second side of the device wafer prior to depositing the dielectric layer.

5. The method of claim 1, wherein the first side of the device wafer is bonded to the first carrier wafer by:
applying an aluminum oxide layer to the device wafer;
applying a high aspect ratio oxide layer to the aluminum oxide layer;
applying a high density plasma oxide layer to the high aspect ratio oxide layer; and
applying the first carrier wafer to the high density plasma oxide layer.

6. The method of claim 1, wherein the perimeter of the device wafer is mechanically trimmed.

7. The method of claim 1, wherein the annular portion has a width of about 2 micrometer to about 5 micrometers.

8. The method of claim 1, wherein the dielectric layer is formed of silicon dioxide.

9. The method of claim 1, wherein the dielectric layer has a thickness of about 3000 angstroms to about 10,000 angstroms.

10. The method of claim 1, wherein the dielectric layer is removed using vapor hydrogen fluoride (VHF).

11. The method of claim 1, wherein the adhesive material is benzocyclobutene.

12. The method of claim 1, wherein the guard ring has a height of about 30 micrometers to about 110 micrometers; or
wherein the patterned bottom layer has a height of about 10 micrometers to about 30 micrometers.

13. The method of claim 1, wherein the removal of the dielectric layer also separates the device wafer into a plurality of dies.

14. A die transfer system, comprising:
a carrier wafer; and
a patterned adhesive layer on an upper surface of the carrier wafer; and
a guard ring on the upper surface of the carrier wafer located over a perimeter of the carrier wafer.

15. The system of claim 14, wherein the guard ring has a width of about 1 micrometer to about 5 micrometers.

16. The system of claim 14, wherein the guard ring has a height of about 30 micrometers to about 110 micrometers.

17. The system of claim 14, wherein the guard ring is formed from the same material as the patterned adhesive bottom layer.

18. The system of claim 14, further comprising a plurality of dies on the patterned bottom layer and surrounded by the guard ring.

19. A method for placing a die on a substrate, comprising:
receiving a die transfer system that comprises:
a carrier wafer;
an adhesive layer on an upper surface of the carrier wafer that comprises a bottom layer and a guard ring over a perimeter of the carrier wafer; and
a plurality of dies on the bottom layer of the adhesive layer and surrounded by the guard ring;
picking a die of the plurality of dies from the die transfer system; and
placing the die upon a substrate.

20. The method of claim 19, wherein a top surface of the guard ring is higher than the plurality of dies.
